(19) United States
(12) Patent Application Publication
(10) Pub. No.: US 2003/0043548 A1
(43) Pub. Date: Mar. 6, 2003

(54) Power supply

(76) Inventor: Henry Cheng, Suisun, CA (US)

Correspondence Address: INTELLECTUAL PROPERTY SOLUTIONS, INCORPORATED, 5717 COLFAX AVENUE, ALEXANDRIA, VA, 22311, US

(21) Appl. No.: 09/941,570

(22) Filed: Aug. 30, 2001

(51) Int. Cl. H05K 7/20

(52) U.S. Cl. 361/720; 361/695

(57) ABSTRACT

A power supply includes a housing, a printed circuit board, at least one electrical element, a fan assembly and a plurality of sockets. The housing has a surface. The printed circuit board is provided in the housing. The electrical element is mounted on the printed circuit board. The fan assembly is also provided in the housing to ventilate the electrical element on the printed circuit board. The sockets are mounted on the surface of the housing to connect a plurality of peripheral devices. When the user terminates the power supply, all of the peripheral devices are simultaneously turned off.

### BACKGROUND OF THE INVENTION

1. Field of the Invention

The present invention relates in general to a power supply capable of connecting plural electronic devices.

2. Description of the Related Art

As shown in FIGS. 1 and 2, a conventional power supply for a computer has a housing 12, a printed circuit board (PCB) 16 housed in the housing 12, and a plurality of electrical elements 18 mounted on the PCB 16. In operation, the temperature of the electrical elements 18 is high. Thus, a fan assembly 14 is further provided in the housing 12 to ventilate the inside of the power supply. Hot air in the housing 12 is drained out via holes 120 on the housing 12 so as to cool down the electrical elements 18. A socket 13 is mounted on the housing 12 for connecting an electronic device that generally is a monitor. By the arrangement, the power supply is able to simultaneously supply the monitor and computer with power. When the user enables/terminates the power supply, both the computer and the monitor are turned on/off.

The conventional power supply has only one socket connected to the monitor. Even the power supply is terminated, the plug of the monitor is still maintained in the socket of the power supply. Thus, the conventional power supply fails to connect other peripheral devices such as a printer, a fax machine, a scanner, a modem and speakers etc. The user has to individually turn on/off each peripheral device, an inconvenient operation. Providing more sockets on the conventional power supply is difficult, because the housing has no sufficient area on its front surface for the extra sockets. It is noted that the holes 120, socket 13 and switch 15 fully occupy the front surface of the power supply.

### SUMMARY OF THE INVENTION

An object of the present invention is to provide a power supply that is capable of connecting a plurality of peripheral devices.

The power supply of the present invention includes a housing, a printed circuit board, at least one electrical element, a fan assembly and a plurality of sockets. The housing has a surface. The printed circuit board is provided in the housing. The electrical element is mounted on the printed circuit board. The fan assembly is also provided in the housing to ventilate the electrical element on the printed circuit board. The sockets are mounted on the surface of the housing to connect a plurality of peripheral devices. When the user terminates the power supply, all of the peripheral devices are simultaneously turned off.

### BRIEF DESCRIPTION OF THE DRAWINGS

The present invention can be more fully understood by reading the subsequent detailed description and examples with references made to the accompanying drawings, wherein:

FIG. 1 is a perspective diagram of a conventional power supply;

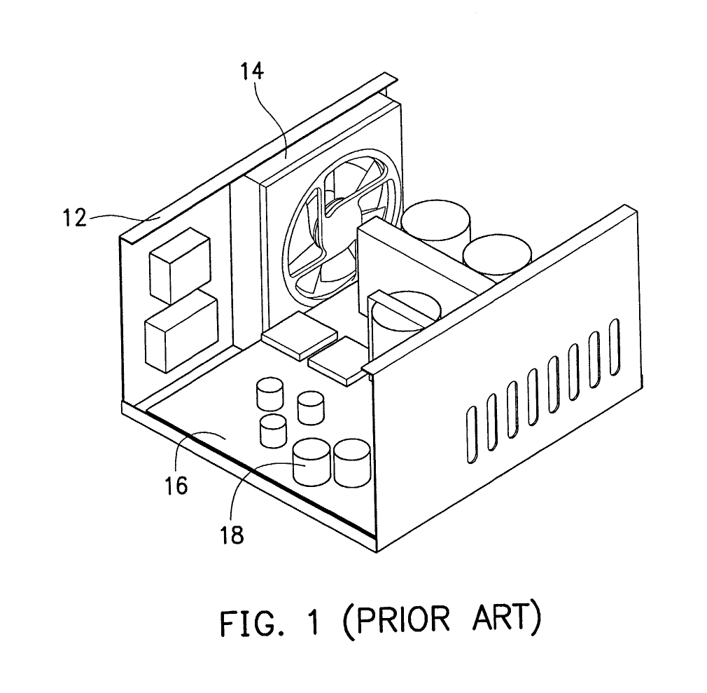

FIG. 2 shows the power supply of FIG. 1 from a different angle;

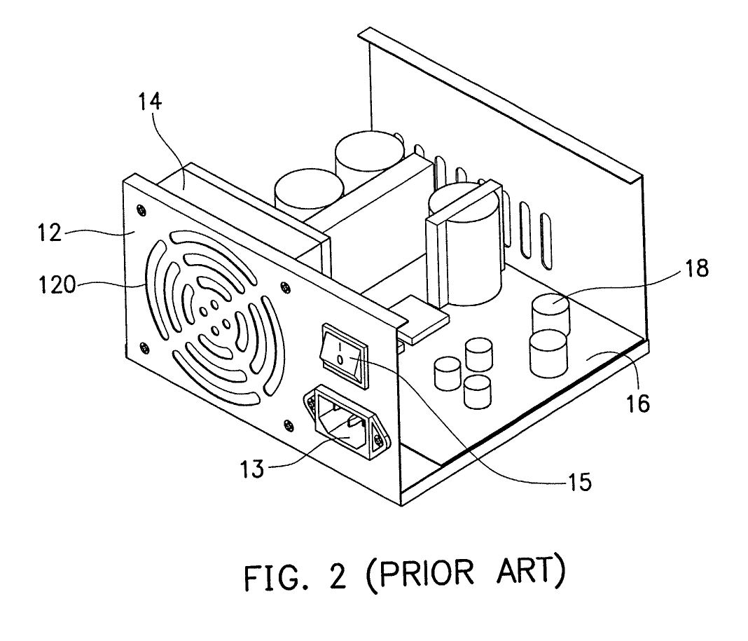

FIG. 3 is a perspective diagram of a power supply in accordance with the present invention;

FIG. 4 depicts the inside of the power supply of FIG. 3; and

FIG. 5 is a perspective diagram of a fan assembly of a power supply in accordance with the present invention.

### DETAILED DESCRIPTION OF THE PREFERRED EMBODIMENT

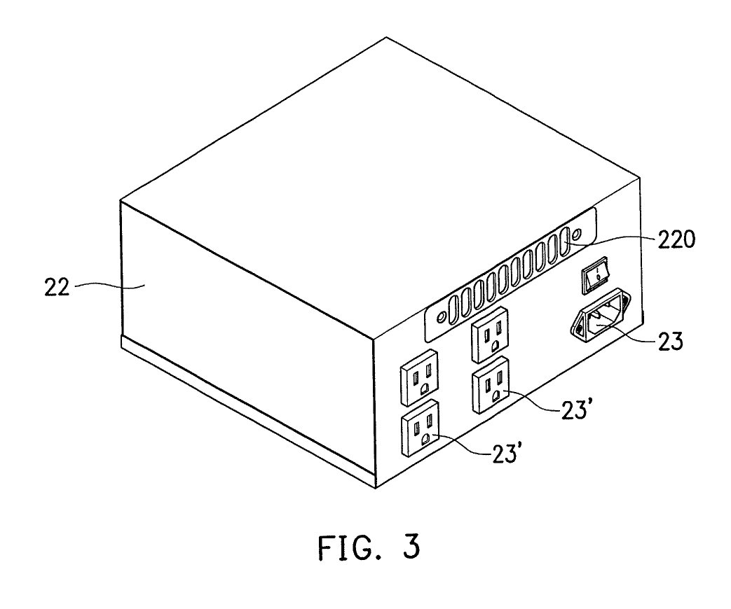

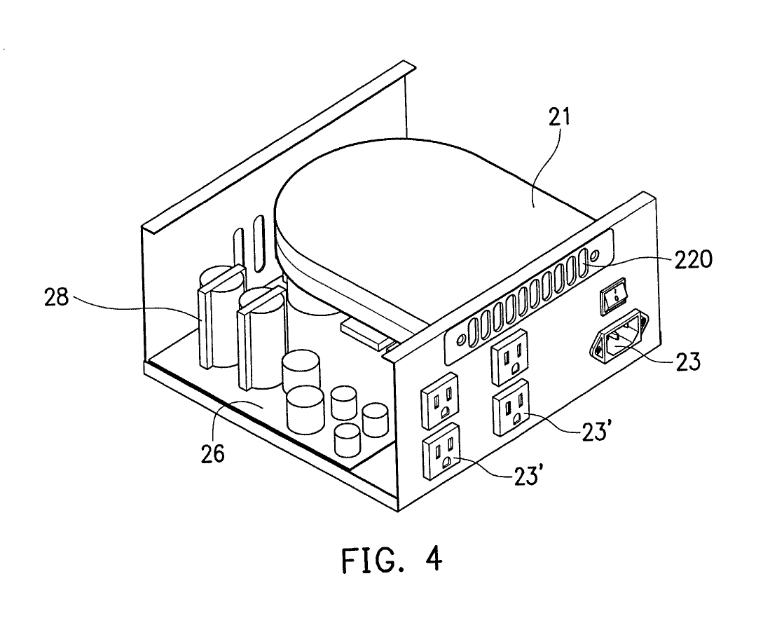

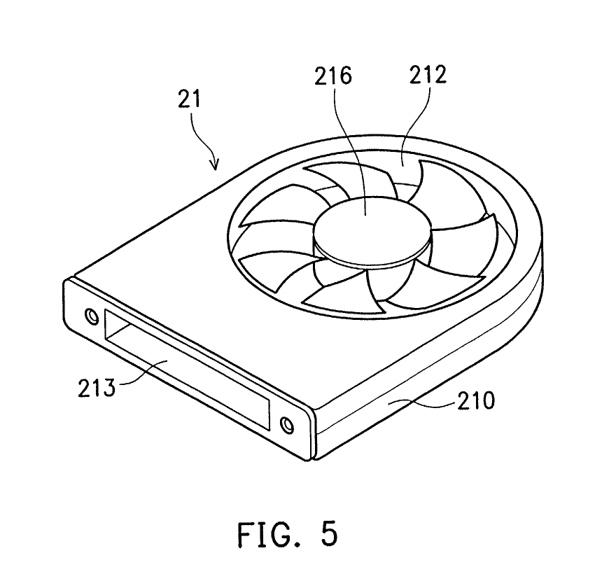

Referring to FIGS. 3 and 4, a power supply of the present invention has a housing 22, a printed circuit board (PCB) 26 housed in the housing 22 and a plurality of electrical elements 28 mounted on the PCB 26. In operation, the temperature of the electrical elements 28 is high. Therefore, a fan assembly 21 is further provided in the housing 22 to ventilate the inside of the power supply and cool down the electrical elements 28. It is noted that the fan assembly 21 is arranged in parallel to the printed circuit board 26 (or the shaft of the fan assembly 21 is perpendicular to the printed circuit board). Such an arrangement is different from that of the conventional power supply. In the conventional power supply, the fan assembly is vertically arranged. In the present invention, however, the fan assembly is horizontally arranged. Referring to FIG. 5, the fan assembly 21 includes a shell 210 and a fan 216. On the top surface of the shell 210 is provided a first hole 212, while on a side surface of the shell 210 is provided a second hole 213. The fan assembly 21 is screwed to the housing 22 of the power supply, with the second hole 213 of the fan assembly 21 communicating the slots 220 on the housing 22. It is noted that in FIG. 5 the fan assembly 21 faces up so as to expose the fan 216 and the first hole 212. In FIG. 4, however, the fan assembly 21 faces down so that the fan 216 and the first hole 212 are invisible. In operation, hot air in the housing 22 is drained out by the fan 216 through the first hole 212 and then the second hole 220.

The present invention horizontally arranges the fan assembly 21 so that the slots 220 can occupy reduced area on the front surface of the power supply. Then, a plurality of sockets 23 and 23′ are allowed on the front surface of the power supply. By the arrangement, the user can connect a plurality of peripheral devices (a printer, a fax machine, a scanner, a modem and speakers etc.) to the power supply. When the power supply is enabled, all of the peripheral devices are simultaneously turned on. On the other hand, the power supply detects and simultaneously turns off all of the peripheral devices to save power. The present invention provides an efficient operation.

While the invention has been described by way of example and in terms of the preferred embodiment, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A power supply comprising:
a housing having a surface;
a printed circuit board provided in the housing;
at least one electrical element mounted on the printed circuit board;
a fan assembly also provided in the housing to ventilate the at least one electrical element on the printed circuit board; and
a plurality of sockets mounted on the surface of the housing.

2. A power supply as claimed in claim 1, wherein the fan assembly has a shaft, and the shaft is perpendicular to the printed circuit board.
